(19) United States
(12) Patent Application Publication
(10) Pub. No.: US 2024/0213033 A1
(43) Pub. Date: Jun. 27, 2024

(54) SELECTIVE ETCHING METHODS AND ETCHING ASSEMBLIES

(71) Applicant: ASM IP Holding B.V., Almere (NL)

(72) Inventors: YongGyu Han, Leuven (BE); Marko Tuominen, Helsinki (FI); Shaoren Deng, Ghent (BE); Vincent Vandalon, Heverlee (BE); Kranthi Kumar Vaidyula, Leuven (BE); Nadadur Veeraraghavan Srinath, Leuven (BE)

(21) Appl. No.: 18/544,516

(22) Filed: Dec. 19, 2023

Related U.S. Application Data
(60) Provisional application No. 63/434,202, filed on Dec. 21, 2022.

(51) Int. Cl. H01L 21/311; H01J 37/32; H01L 21/027; H01L 21/67

(52) U.S. Cl. CPC H01L 21/31144; H01J 37/32899; H01L 21/0271; H01L 21/31116; H01L 21/67069; H01J 2237/3341

(57) ABSTRACT

The current disclosure relates to methods and assemblies for selectively etching a material from a first surface of a substrate relative to a second surface of the same substrate. The second surface of the substrate is covered by an organic polymer layer and the first surface is etched by a reactive species generated from NF₃-containing plasma. The current disclosure further relates to semiconductor structures and devices formed by using the methods or assemblies of the disclosure.

### CROSS-REFERENCE TO RELATED APPLICATIONS

This application claims priority to and the benefit of U.S. Provisional Application No. 63/434,202, filed Dec. 21, 2022, the entirety of which is incorporated by reference herein.

### FIELD OF INVENTION

The present disclosure generally relates to methods and assemblies for processing semiconductor substrates. More particularly, the disclosure relates to methods and assemblies for selectively etching a particular material on a semiconductor substrate.

### BACKGROUND OF THE DISCLOSURE

Various dielectric, insulating and conductive materials are used in semiconductor applications as to form semiconductor devices and further integrated circuits. The growing complexity of the devices and device architectures necessitates the use of numerous processing steps, including repeated patterning, to create them. The cost of using different process steps is always a concern, and selective deposition of materials is being explored as an option to enable device scaling and/or increased performance while keeping the cost and complexity of the manufacturing process at bay.

Selective etching, in which specific materials are preferentially etched over other materials is emerging as a promising process to create multi-layered semiconductor structures without intermittent patterning. However, the selection of selective etching processes for various material combinations is limited. Thus, there is need in the art for more etching processes targeting new material combinations, and to improve the accuracy of the existing ones to enable further scalability and versatility semiconductor devices.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively etching material from a first surface of a substrate relative to a second surface of the same substrate. Embodiments of the current disclosure further relate to methods of fabricating semiconductor devices, and to semiconductor processing assemblies.

Various embodiments of the current disclosure relate to a method of selectively etching material from a first surface of a substrate relative to a second surface of the substrate. The method comprises providing the substrate having a first surface comprising an etchable material and a second surface covered by an organic polymer layer in a reaction chamber, providing reactive species generated from NF₃-containing plasma into the reaction chamber to selectively etch the etchable material.

In some embodiments, the organic polymer layer comprises polyimide. In some embodiments, the organic polymer is substantially not etched.

In some embodiments, the NF₃-containing plasma further comprises at least one noble gas. In some embodiments, the NF₃-containing plasma comprises argon. In some embodiments, the NF₃-containing plasma is generated from a gas mixture consisting substantially only of argon and NF₃. In some embodiments, the NF₃-containing plasma is generated from a gas mixture containing between about 1% and about 90% NF₃. In some embodiments, the NF₃-containing plasma is generated remotely.

In some embodiments, the method is performed at a temperature of between about 30° C. and about 250° C.

In some embodiments, the first surface and the second surface have chemically different composition. In some embodiments, the first surface comprises silicon. In some embodiments, the first surface comprises one or more of SiO₂, SiN, SiC, SiCN, SiON and SiOC. In some embodiments, the second surface comprises a metal. In some embodiments, the metal is selected from a group consisting of aluminum, copper, tungsten, cobalt, nickel, niobium, iron, molybdenum, zinc, ruthenium, manganese, titanium, tin and vanadium. In some embodiments, the second surface comprises one or more of an elemental metal, metal oxide, metal nitride.

In some embodiments, the first surface and the second surface form different surfaces of a structure. In some embodiments, the second surface forms an inside surface of a gap.

In another aspect, a method of selectively etching material from a first surface of a substrate relative to a second surface of the substrate is disclosed, wherein the method comprises providing the substrate having a first surface comprising an etchable material, and a second surface in a first reaction chamber, selectively depositing a layer comprising polyimide on the second surface by a cyclic deposition process, wherein the cyclic deposition process comprises providing pyromellitic dianhydride and a diamine into the reaction chamber alternately and sequentially. The method further comprises providing the substrate in a second reaction chamber, and providing reactive species generated from NF₃-containing plasma into the reaction chamber to selectively etch the etchable material. In some embodiments, the first reaction chamber and the second reaction chamber are in the same deposition assembly.

In a further aspect, a method of forming a structure comprising a selective etching process according to the current disclosure is disclosed.

In yet another aspect, a semiconductor device formed by a method comprising a selective etching process according to the current disclosure is disclosed.

In a yet further aspect, a semiconductor processing assembly for processing a substrate is disclosed. The processing assembly comprises a reaction chamber constructed and arranged to hold a substrate having a first surface comprising an etchable material and a second surface covered by an organic polymer layer, a first reactant source containing NF₃ and a second reactant source containing a noble gas. The processing assembly further comprises a plasma generator in fluid communication with the first reactant source and the second reactant source for generating NF₃-containing plasma and a reactant injection system constructed and arranged to provide the NF₃-containing plasma into the reaction chamber.

In some embodiments, the semiconductor processing assembly according to the current disclosure further comprises a second reaction chamber for selectively depositing an organic polymer layer on the second surface.

In some embodiments, the semiconductor processing assembly according to the current disclosure comprises a computer programmed to deposit the organic polymer on the second surface before providing the NF₃-containing plasma into the reaction chamber.

In a yet further aspect, a method of forming a patterned feature on a substrate is disclosed. The method comprises selectively etching material from a first surface of a substrate relative to a second surface of the substrate according to the current disclosure.

### BRIEF DESCRIPTION OF THE DRAWINGS

The accompanying drawings, which are included to provide a further understanding of the disclosure and constitute a part of this specification, illustrate exemplary embodiments, and together with the description help to explain the principles of the disclosure. In the drawings FIG. 1 is a block diagram of exemplary embodiments of a method according to the current disclosure.

FIG. 2 is a schematic presentation of exemplary embodiments of a method according to the current disclosure.

FIG. 3 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In various processing steps for semiconductor devices, certain areas of a substrate need to be removed. Patterning is time-consuming and expensive, and therefore, area-selective etching may be used as an alternative. However, high-fidelity etching is difficult to achieve, and new materials to form as etch-stop layers are sought after. Being able to selectively deposit such materials is a further complication of the selective etch approach. The inventors of the current disclosure developed methods to utilize organic polymer-containing, selectively depositable material to be used as an etch-stop or hard mask material that may be utilized for dry etching in a variety of contexts, including with different material combinations, as well as in three-dimensional semiconductor structures.

In an aspect, a method of selectively etching material from a first surface of a substrate relative to a second surface of the substrate is disclosed. The method comprises providing the substrate having a first surface comprising an etchable material and a second surface covered_by an organic polymer layer in a reaction chamber, providing reactive species generated from NF₃-containing plasma into the reaction chamber to selectively etch the etchable material.

By NF₃-containing plasma is herein meant plasma that is generated from a gas or gas mixture containing NF₃. NF₃-containing plasma may therefore contain various active and/or reactive species, and some of them may originate from other gases than NF₃. Thus, the current disclosure relates to dry etching methods.

Selective etching processes according to the current disclosure may be used to remove material from a substrate surface selectively. The material to be removed may be referred to as the etchable material. In some embodiments, the etchable material may be a material comprised in the substrate, or deposited on the substrate. In some embodiments, the etchable material has been deposited on the substrate on purpose. In some embodiments, the etchable material may be an unwanted contaminant on the substrate surface. For example, in some embodiments the etchable material to be etched is parasitic material grown unwantedly from an area-selective deposition process.

In the current disclosure, an organic polymer layer covers the second surface of the substrate at the time of etching. By the organic polymer layer covering the second surface is herein meant that a substantially pinhole-free layer having a thickness is positioned on the second surface but not on the first surface. The organic polymer, such as polyimide-containing material, may be formed on the second surface by a cyclic deposition process (molecular layer deposition, MLD). The selectivity of etching according to the current disclosure is determined by the organic polymer layer. The material of the second surface below the organic polymer layer may be susceptible to etching under the conditions described herein. The thickness of the organic polymer layer may vary from application to application. For example, polymer layers comprising polyimide may be very resistant to NF₃ plasma etching. In such embodiments, even a thin organic polymer layer is sufficient to protect the underlying material of the second surface. However, to achieve appropriate etch selectivity, the organic polymer layer should be substantially pinhole-free to avoid areas of the second surface from being etched. Without limiting the current disclosure to any specific theory, the minimum thickness of the organic polymer layer may be determined by the thickness in which a sufficiently continuous (pinhole-free) organic polymer layer is achieved. In some embodiments, the organic polymer layer has a thickness from about 1 nm to about 50 nm, such as from about 1 nm to about 30 nm, from about 1 nm to about 20 nm, from about 1 nm to about 10 nm or from about 1 nm to about 5 nm. In some embodiments, the organic polymer layer has a thickness of about 2 nm, about 3 nm, about 4 nm or about 7 nm.

Further, the fidelity of etching depends on how accurately the organic polymer layer is deposited on the second surface. Methods are known to those skilled in the art to regulate the accuracy of depositing an organic polymer layer, such as a polyimide-containing layer. For example, hydrogen plasma may be used to trim the edges of the organic polymer layer, and methods directing the organic polymer on specific material or to a certain area of a three-dimensional structure are known in the art.

Selectivity in etching may be described as an etch ratio (i.e. etch selectivity), which is the ratio of etch rate of the material on the first surface relative to the etch rate of the material on the second surface. In the current disclosure, the material exposed to etching on the second surface is the organic polymer layer covering the second surface. In some embodiments, the organic polymer layer is etched to a lesser extent than the first surface. In some embodiments, the etch selectivity of the process according to the current disclosure is about 2 or greater. For example, etch selectivity may be from about 2 to about 1,000, such as from about 2 to about 800, or from about 2 to about 500, or from about 2 to about 200, or from about 2 to about 100, or from about 2 to about 50. For example, the etch selectivity may be about 3, about 5, about 10, about 25 or about 40. In some embodiments, etch selectivity may be from about 5 to about 1,000, or from about 10 to about 1,000, or from about 50 to about 1,000, or from about 100 to about 1,000, or from about 500 to about 1,000. In some embodiments, the organic polymer layer, such as polyimide-comprising layer, is substantially not etched. In such embodiments, etch selectivity may be difficult to assess.

In some embodiments, the selective etching process is a continuous etching process. In some embodiments a substrate is contacted with reactive species generated from NF₃-containing plasma as described herein for a sufficient time to achieve the desired level of etching in one step. The substrate is contacted with reactive species generated from NF₃-containing plasma by providing the NF₃-containing plasma into the reaction chamber (i.e. plasma pulse). In some embodiments, the etch process is repeated at least once. In other words, providing the reactive species generated from NF₃-containing plasma into the reaction chamber may be repeated at least once. The reaction chamber may be purged between consecutive plasma pulses.

In some embodiments, the etchable material is etched at a speed from about 0.05 Å/s to about 5 Å/s, such as at a speed from about 0.1 Å/s to about 4 Å/s. In some embodiments, the etchable material is etched at a speed from about 0.05 Å/s to about 1 Å/s, or at a speed from about 1 Å/s to about 5 Å/s. In some embodiments, the etchable material is etched at a rate from about 1 Å/s to about 4 Å/s. The etching speed may depend on the composition of the etchable material. For example, SiO₂ may be etched faster than SiN, or SiCN. The etching speed may be adjusted through process parameters, such as ion energy (plasma power, bias power and pressure) and substrate temperature.

In this disclosure, “gas” can include material that is a gas at normal temperature and pressure (NTP), a vaporized solid and/or a vaporized liquid, and can be constituted by a single gas or a mixture of gases, depending on the context. The NF₃-containing plasma is generated from NF₃-containing gas. The gases used for plasma generation may comprise additional elements and/or compounds. For example, He and Ar and any combination thereof may be used in plasma generation. Further process gases may be utilized in the process without generating plasma from them. A gas other than a process gas, i.e., a gas introduced without passing through a precursor injector system, other gas distribution device, or the like, can be used for, e.g., sealing the reaction space, and can include a seal gas.

In some embodiments, the method according to the current disclosure is performed at a temperature of between about 20° C. and about 250° C. The selected temperature may affect the etching speed, and the temperature may be selected according to the application and other process parameters used. In some embodiments, the method is performed at a temperature between about 40° C. and about 250° C. or at a temperature between about 80° C. and about 250° C. In some embodiments, the method is performed at a temperature between about 100° C. and about 250° C. or at a temperature between about 150° C. and about 250° C. In some embodiments, the method is performed at a temperature between about 20° C. and about 200° C. or at a temperature between about 20° C. and about 150° C. or at a temperature between about 20° C. and about 100° C. In some embodiments, the method is performed at a temperature of between about 20° C. and about 80° C. or at a temperature between about 20° C. and about 60° C., such as at a temperature between about 40° C. and about 50° C. or at a temperature between about 30° C. and about 40° C.

### NF₃-Containing Plasma

NF₃-containing plasma is used in the current disclosure to etch material of the first surface. Thus, one or more of the materials present in the first surface are susceptible to etching by NF₃-containing plasma. It is to be understood that the term “NF₃-containing plasma” is an abbreviation for plasma generated from a gas mixture containing NF₃. The etching species in the reaction chamber may be variable active and reactive species. In some embodiments, the NF₃-containing plasma further comprises at least one noble gas. The noble gas may be selected from a group consisting of helium (He), neon (Ne), argon (Ar), krypton (Kr) and xenon (Xe), and mixtures thereof. In some embodiments, the NF₃-containing plasma comprises argon (Ar). In some embodiments, the NF₃-containing plasma is generated from a gas mixture consisting substantially only of Ar and NF₃. In some embodiments, the NF₃-containing plasma comprises helium (He). In some embodiments, the NF₃-containing plasma is generated from a gas mixture consisting substantially only of He and NF₃. In some embodiments, the NF₃-containing plasma comprises Ar and He. In some embodiments, the NF₃-containing plasma is generated from a gas mixture consisting substantially only of Ar, He and NF₃.

The NF₃ content of the gas from which the plasma is generated may affect the amount and nature of the reactive species generated from the plasma. This, in turn, may affect etching speed. In some embodiments, the NF₃-containing plasma is generated from a gas mixture containing between about 0.01% and about 95% NF₃. In some embodiments, NF₃-containing plasma is generated from a gas mixture containing between about 0.01% and about 10% NF₃ or between about 0.01% and about 30% NF₃ or between about 0.01% and about 50% NF₃ or between about 0.01% and about 70% NF₃. In some embodiments, NF₃-containing plasma is generated from a gas mixture containing between about between about 50% and about 95% NF₃ or between about 80% and about 95% NF₃. In some embodiments, NF₃-containing plasma is generated from a gas mixture containing between about 0.05% and about 50% NF₃ or between about 0.1% and about 50% NF₃ or between about 1% and about 50% NF₃ or between about 5% and about 50% NF₃ or between about 10% and about 50% NF₃ or between about 20% and about 50% NF₃. For example, the NF₃-containing plasma is generated from a gas mixture containing between about 0.01% and about 5% NF₃ or between about 5% and about 10% NF₃, such as about 3% NF₃.

The gas mixture used to generate NF₃-containing plasma may contain additional gases. For example, the gas mixture used to generate NF₃-containing plasma may comprise NH₃. The additional gases may be used to amend the proportions of various reactive and/or active species. This may affect the etching or speed thereof of different materials to be etched. The concentration of an additional gas, such as NH₃, in the gas mixture may be higher than that of NF₃.

In some embodiments, the NF₃-containing plasma is generated remotely. By remote plasma is herein meant a plasma generation scheme, in which the plasma is generated outside the reaction chamber. The remotely-generated plasma may be, for example, inductively coupled plasma. In initial tests of the invention, frequency of 400 kHz and power of 8 kW were used.

### Purge

The term “purge” or “purging” may refer to a procedure in which vapor phase reactants and/or vapor phase byproducts, such etching products, are removed from the substrate surface for example by evacuating the reaction chamber with a vacuum pump and/or by replacing the gas inside a reaction chamber with an inert or substantially inert gas such as argon or nitrogen. Purging may be effected after providing reactive species generated from NF₃-containing plasma into the reaction chamber. Purging may avoid or at least reduce gas-phase interactions between gases present in the reaction chamber. It shall be understood that a purge can be effected either in time or in space, or both. For example in the case of temporal purges, a purge step can be used e.g. in the temporal sequence of providing a reactant, such as NF₃-containing plasma, into a reactor chamber, providing a purge gas into the reactor chamber, and providing the reactant again into the reactor chamber. In a typical temporal purge, the substrate does not move. In the case of spatial purge, a purge step can take the following form: moving a substrate from a first location to which a reactant is continually supplied, through a purge gas curtain, to a second location to which the same or a different reactant is continually supplied. The next location may be a different processing station of a multi-station reaction chamber. The next processing step, such as depositing a material, may be performed in the next location.

Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where high aspect ratio structures or other structures with complex surface morphology are processed.

### Organic Polymer Layer

The organic polymer layer covering the second surface serves to protect the second surface form being etched. Thus, the second surface being covered by the organic polymer is a not-etchable surface. In some embodiments, the organic polymer layer comprises polyimide. The organic polymer layer may, for example, comprise polyimide and polyamic acid. In some embodiments, polyimide may be deposited at a temperature from about 150° C. to about 200° C., such as from about 170° C. to about 190° C., using 1,6-diaminohexane and pyromellitic dianhydride as precursors for the polymer formation.

An organic polymer layer may be provided on the second surface by a cyclic deposition process. For example, polyimide-comprising layer may be deposited by providing an acid anhydride and a diamine alternately and sequentially into a reaction chamber to form an organic polymer layer. The organic polymer layer may be selectively deposited on the second surface by providing a two precursors, such as a diamine and an acid anhydride, into the reaction chamber alternately and sequentially. In some embodiments a diamine used to deposit the organic polymer layer comprises 1,6-diaminohexane (DAH). In some embodiments the acid anhydride used to deposit the organic polymer layer comprises a dianhydride. In some embodiments the dianhydride is pyromellitic dianhydride (PMDA). In some embodiments the substrate is held at a temperature of greater than about 80° C. or greater than about 170° C. during depositing the organic polymer layer. For example, the organic polymer layer may be deposited at a temperature of about 100° C., about 120° C., about 150° C., about 170° C., about 190° C., about 200° C. or about 220° C. In some embodiments, the organic polymer layer comprises polyamide. In some embodiments the organic polymer that is selectively deposited is a mixture of polyamide, polyimide, and other polymeric material.

In some embodiments the organic polymer material is deposited on the second surface relative to the first surface with a selectivity of above about 50% or about 70% or above about 90% or about 95%. In some embodiments, the first surface is pretreated to improve the contrast between the first surface and the second surface and to drive the deposition of the organic polymer layer on the second surface. For example, silylation may be used to pretreat the first surface. In some embodiments, a dielectric first surface is selectively silylated relative to the second surface. In some embodiments, the first surface is blocked from organic polymer deposition by exposure to a silylation agent, such as allyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA).

In some embodiments, the blocking may aid in subsequent selective deposition of an organic polymer layer on a second metal surface, as described below. Thus, blocking a dielectric surface may, in some embodiments, allow the selective deposition of an organic polymer on another surface, such as a metal surface or a dielectric surface of different composition. In some embodiments, blocking, such as silylation, does not require a specific removal step before an etching process according to the current disclosure.

In some embodiments, selective deposition of the organic polymer layer on the second surface occurs at a growth rate of about 0.5 Å/cycle to about 20 Å/cycle, about 1 Å/cycle to about 15 Å/cycle, about 1.5 Å/cycle to about 10 Å/cycle, or about 2 Å/cycle to about 8 Å/cycle. In some embodiments the growth rate of the organic polymer layer on the metal surface is more than about 0.5 Å/cycle, more than about 1 Å/cycle, more than about 3 Å/cycle, more than about 5 Å/cycle while on the upper end the growth rate in some embodiments is less than about 20 Å/cycle, less than about 15 Å/cycle, less than about 10 Å/cycle or less than about 8 Å/cycle. Selectivity for the metal surface relative to a second surface is maintained at these growth rates in some embodiments.

The thickness of the organic polymer layer depends on the application. A thin organic polymer layer is sufficient in embodiments, in which the organic polymer layer is substantially not etched by the etching process according to the current disclosure. In embodiments in which the organic polymer layer is etched by the plasma, a sufficiently thick layer is needed to keep the second surface protected from the etchant sufficiently long. However, it may be advantageous to continue etching long enough to remove the organic polymer layer, as additional cleaning processes may be avoided. As described above, the minimum thickness needed for the organic polymer layer may relate to the thickness at which a pinhole-free layer can be formed.

In some embodiments, the organic polymer layer may be treated after deposition to improve its etch-resistance or other properties. In some embodiments, the substrate comprising the organic polymer layer is heated for a period of about 1 minute to about 15 minutes. In some embodiments, the substrate is baked at a temperature of about 200° C. to about 500° C. Alternatively or in addition, the substrate comprising the organic polymer layer may be treated with a curing agent, such as a dehydrating agent. In some embodiments, the substrate may be treated with acetic anhydride or other chemicals to increase the proportion of polyimide in the organic polymer layer. However, in some embodiments, the organic polymer layer is sufficiently etch-resistant as deposited, and no additional treatments are necessary.

### First Surface and Second Surface

In some embodiments, the first surface and the second surface have chemically different composition. However, in some embodiments, the first surface and the second surface form different surfaces of a structure. In such embodiments, the chemical composition of the first surface and the second surface may be the same or different.

In embodiments, in which the first surface and the second surface have different chemical composition, there are various alternatives to the surface composition.

### First Surface

In some embodiments, the first surface comprises silicon. In some embodiments, the first surface comprises silicon. In some embodiments, the first surface comprises one or more of SiO₂, SiN, SiC, SiCN, SiON, SiOC and SiOCN.

As used herein, silicon oxide refers to a material that includes silicon and oxygen. Silicon oxide can be represented by the formula SiOₓ, where x can be between 0 and 2 (e.g., SiO₂). In some cases, the silicon oxide may not include stoichiometric silicon oxide. In some cases, the silicon oxide can include other elements, such as carbon, nitrogen (SiON), hydrogen, or the like.

Silicon carbide (SiC) can refer to a material that includes silicon and carbon. Silicon carbide need not necessarily be a stoichiometric composition. An amount of silicon can range from 5 to 50 at %; an amount of carbon can range from about 50 to about 95 at %. In some embodiments, SiC films may comprise one or more elements in addition to Si and C, such as H or N (SiCN).

Silicon nitride (SiN) can refer to a material that includes silicon and nitrogen. Silicon nitride need not necessarily be a stoichiometric composition, but may have stoichiometric composition, such as Si₃N₄. An amount of silicon can range from 5 to 50 at %; an amount of nitrogen can range from about 50 to about 90 at %. In some embodiments, SiN films may comprise one or more elements in addition to Si and N, such as H or C (SiCN).

Silicon oxycarbide (SiOC) can refer to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, SiOC thin films may comprise one or more elements in addition to Si, O, and C, such as H or N. In some embodiments, the SiOC films may comprise Si—C bonds and/or Si—O bonds. In some embodiments, the SiOC films may comprise Si—C bonds and Si—O bonds and may not comprise Si—N bonds. In some embodiments, the SiOC films may comprise Si—H bonds in addition to Si—C and/or Si—O bonds. In some embodiments, the SiOC films may comprise more Si—O bonds than Si—C bonds, for example, a ratio of Si—O bonds to Si—C bonds may be from about 1:10 to about 10:1. In some embodiments, the SiOC films may comprise from about 0% to about 50% carbon on an atomic basis. In some embodiments, the SiOC films may comprise from about 0.1% to about 40%, from about 0.5% to about 30%, from about 1% to about 30%, or from about 5% to about 20% carbon on an atomic basis. In some embodiments, the SiOC films may comprise from about 0% to about 70% oxygen on an atomic basis. In some embodiments, the SiOC films may comprise from about 10% to about 70%, from about 15% to about 50%, or from about 20% to about 40% oxygen on an atomic basis. In some embodiments, the SiOC films may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, the SiOC films may comprise from about 0.1% to about 40%, from about 0.5% to about 30%, from about 1% to about 30%, or from about 5% to about 20% hydrogen on an atomic basis. In some embodiments, the SiOC films may not comprise nitrogen. In some other embodiments, the SiOC films may comprise from about 0% to about 40% nitrogen on an atomic basis (at %). By way of particular examples, SiOC films can be or include a layer comprising SiOCN. In some embodiments, silicon oxycarbide can be represented by the chemical formula Si_{z}OₓC_{y}, where z can range from about 0 to about 2, x can range from about 0 to about 2, and y can range from about 0 to about 5.

Silicon oxycarbonitride (SiOCN) refers to material that comprises silicon, oxygen, nitrogen and carbon. As used herein, unless stated otherwise, SiOCN is not intended to limit, restrict, or define the bonding or chemical state, for example, the oxidation state of any of Si, O, C, N and/or any other element in the film. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

According to some aspects of the present disclosure, selective etching can be used to remove material from a first surface of a substrate relative to a second surface of the substrate. The two surfaces may have different material properties.

In some embodiments, the first surface is a dielectric surface. In some embodiments, the first surface is a low-k surface. In some embodiments, the first surface comprises an oxide. In some embodiments, the first surface comprises a nitride. In some embodiments, the first surface comprises silicon. Examples of silicon-comprising dielectric materials include silicon oxide-based materials, including grown or deposited silicon dioxide, doped and/or porous oxides and native oxide on silicon. In some embodiments, the first surface comprises one or more of SiO₂, SiN, SiC, SiCN, SiON, SiOC and SiOCN. In some embodiments, the first surface comprises silicon oxide. In some embodiments, the first surface is a silicon oxide surface, such as a native oxide surface, a thermal oxide surface or a chemical oxide surface. In some embodiments, the first surface comprises silicon oxide-based material. In some embodiments, the first surface comprises SiN. In some embodiments, the first surface comprises carbon. In some embodiments, the first surface comprises SiOC.

In some embodiments, the first surface comprises a metal oxide. For example, the metal oxide may be a high k metal oxide. Thus, in some embodiments, a first metal oxide surface is selectively etched relative to a second surface covered by an organic polymer layer. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface, or a combination thereof. In some embodiments, the first surface is a metal oxide surface selected from aluminum oxide, hafnium oxide, zirconium oxide, lanthanum oxide and combinations thereof. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the first surface comprises hydroxyl (—OH) groups. In some embodiments, the first surface may additionally comprise hydrogen (—H) terminations, such as an HF dipped Si or HF dipped Ge surface.

In some embodiments, a first dielectric surface of a substrate is selectively etched relative to a second, different dielectric surface of the substrate. In some such embodiments, the dielectric surfaces have different compositions (e.g., silicon, silicon nitride, carbon, silicon oxide, silicon oxynitride, germanium oxide). In some embodiments, a passivation blocking agents, such as silylation, is used to improve contrast between two dielectric surfaces before depositing a passivation layer on the first surface.

The term dielectric is used in the description herein for the sake of simplicity in distinguishing from the other surface, namely the metal or metallic surface. It will be understood by those skilled in the art that not all non-conducting surfaces are dielectric surfaces. For example, the metal or metallic surface may comprise an oxidized metal surface that is electrically non-conducting or has a very high resistivity.

In some embodiments, material of the first dielectric surface of a substrate is etched relative to a second metal or metallic surface of the substrate. In some embodiments, a first dielectric surface of a substrate is selectively etched relative to a second conductive (e.g., metal or metallic) surface of the substrate. In some embodiments the first surface and the second surface are adjacent to each other.

### Second Surface

The term metal oxide can refer to metal that includes a metal and oxygen. The metal or can be, for example, one or more of aluminum, titanium, tin, hafnium, zirconium, indium, cesium, molybdenum, copper, cobalt, ruthenium, tungsten, zinc, nickel, vanadium and niobium.

In some embodiments, the second surface may comprise a metal surface covered by an organic polymer layer, for example a Cu surface covered by an organic polymer layer. That is, in some embodiments, the second surface may comprise a metal surface covered by an organic polymer layer such as a polyimide layer. In some embodiments, the second surface comprises a metal oxide, elemental metal, or metallic surface. In some embodiments, the second metal or metallic surface comprises an organic polymer layer comprising polyamic acid, polyimide, or other polymeric material.

In some embodiments an organic polymer layer such as a polyamide, polyimide or a combination thereof, optionally including other polymers, is selectively deposited on a second dielectric surface of a substrate relative to a first, different dielectric surface. In some such embodiments, the dielectrics have different compositions (e.g., silicon, silicon nitride, carbon, silicon oxide, silicon oxynitride, germanium oxide).

In some embodiments, the second surface comprises a metal. In some embodiments, the second surface comprises metallic material.

For embodiments in which a surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, the metal or metallic surface comprises zinc (Zn). In some embodiments, the metal or metallic surface comprises ruthenium (Ru). In some embodiments, the metal or metallic surface comprises manganese (Mn). In some embodiments, the metal or metallic surface comprises titanium (Ti). In some embodiments, the metal or metallic surface comprises tin (Sn). In some embodiments, the metal or metallic surface comprises vanadium (V). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo. In some embodiments, the metal or metallic surface comprises a metal selected from a group consisting of Cu, Co, Ru, W and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the second surface is a metal surface, wherein the metal is selected from a group consisting of Al, Cu, W, Co, Ni, Nb, Fe, Mo, Zn, Ru, Mn, Ti, Sn and V. In some embodiments, the second surface comprises one or more of an elemental metal, metal oxide, metal nitride. In some embodiments, the organic polymer layer on a metal or metallic surface inhibits, prevents or reduces the etching of the material of the metal or metallic surface. In some embodiments, the second surface comprises silicon germanium (SiGe). In some embodiments, the second surface is a SiGe surface.

In some embodiments, the second surface comprises a metal oxide, metal nitride, elemental metal, or metallic surface. The second surface is covered with an organic polymer layer comprising polyamic acid, polyimide, and/or other polymeric material.

In some embodiments, the second surface comprises carbon. In some embodiments, the second surface comprises amorphous carbon. In some embodiments, the second surface substantially consists of amorphous carbon. In some embodiments, the second surface comprises spin-on carbon. In some embodiments, the second surface substantially consists of spin-on carbon. For example, the spin-on carbon may be a hard mask for patterning.

### Structures

In some embodiments, the first surface and the second surface form different surfaces of a structure. In some embodiments, the second surface forms an inside surface of a gap. The inside surface may have the same or a different material composition than other surfaces of the structure. A gap comprises a side wall, and the organic polymer layer may cover a side wall of the gap. A gap may comprise a bottom, and the organic polymer layer may cover the bottom of the gap. The gap may be filled with the organic polymer layer, or the organic polymer layer may conformally cover at least a side wall or a bottom of the gap.

A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap. A gap may comprise a top and a bottom. An upper part of a gap is the area at the opening of the gap, and the bottom of the gap is the part of the gap distal to the opening of the gap. The area outside the gap is termed the top surface of a gap, such as the topmost horizontal part of a fin, or an area of the substrate between holes or vias.

In some embodiments, in which the second surface forms an inside surface of a gap, the gap may be filled with the organic polymer layer. The filling may be non-selective by selecting the deposition conditions of the organic polymer layer appropriately. The organic polymer layer maybe then removed by, for example, plasma treatment, such as hydrogen plasma treatment, until the top surface of the structure is exposed.

In some embodiments, the organic polymer layer is deposited to substantially fill a gap in the substrate. In some embodiments, the organic polymer layer is deposited until its surface is substantially flush with the top surface of the gap. In some embodiments, the organic polymer layer is deposited until it grows out of the gap. In some embodiments, the organic polymer layer is not deposited laterally outside the gap. In some embodiments, the organic polymer layer is deposited laterally outside the gap. In some embodiments, the method according to the current disclosure comprises an etch-back phase to adjust the surface of the organic polymer layer. In some embodiments, trimming of the substrate after depositing organic polymer layer comprises an etch-back of the organic polymer layer.

The purpose of depositing organic polymer layer inside the gap is to avoid the etching of the material in the gap. The organic polymer layer is a sacrificial material that is not necessarily present in the final structure or device according to the current disclosure. Therefore, the deposition of the organic polymer layer does not need to be uniform in the gap, and the deposition of the organic polymer layer does not need to fill the gap completely. Therefore, the organic polymer layer may form an air gap in the gap. In other words, the gap can be pinched off by the growth of the organic polymer layer, leaving an empty cavity inside the gap. Without limiting the current disclosure to any specific theory, gravity or other physical conditions may affect the organic polymer layer also after deposition. Thus, in some embodiments, the organic polymer layer may collapse, or otherwise deform so that the cavity is not visible, or present. Further, the surface of the organic polymer layer may be concave or otherwise uneven. In some embodiments, the inner surface of the gap comprises material on which the organic polymer can be selectively grown as described above. However, also materials on which the organic polymer does not grow selectively on under the deposition conditions in question may be present on the inside surface of the gap. The organic polymer layer may or may not be deposited on such additional materials. For example, in some embodiments, same material as on the first surface (i.e. top surface) may be present on the inside of the gap. However, the organic polymer layer is inherently deposited on itself. It may therefore reach the top of the gap even in embodiment in which the inside surface of the gap contains materials on which the organic polymer layer does not deposit.

In some embodiments, the organic polymer layer is deposited substantially conformally on a side wall of the gap. In some embodiments, the organic polymer layer is deposited on the side wall of a gap, and not on the bottom of the gap. For example, the bottom of the gap may comprise material on which the organic polymer does not grow under the deposition conditions in question, whereas the side wall contain material on which the organic polymer layer grows.

In some embodiments, the second surface forms a horizontal top surface of a gap. For example, a pretreatment described above may be performed to block the growth of the organic polymer layer on the substrate by silylation. The blocking may be selectively removed from the top surface of the structure by a plasma treatment, for example. This will allow the growth of the organic polymer on the top surface but not on the inside surface of the gap, such as on the side walls. Consequently, the top surface will form the second surface and is protected from etching, whereas the areas from which the blocking, such as silylation, is removed, are exposed to etching. Further, if the blocking has been formed on both the top surface and the bottom of the gap, which extend in the same horizontal direction, the intensity of the removal of blocking may be adjusted to remove the blocking only from the top surface and to keep the bottom of the gap blocked from being covered by the organic polymer layer.

In another aspect, a method of selectively etching material from a first surface of a substrate relative to a second surface of the substrate is disclosed, wherein the method comprises providing the substrate having a first surface comprising an etchable material, and a second surface in a first reaction chamber, selectively depositing a layer comprising polyimide on the second surface by a cyclic deposition process, wherein the cyclic deposition process comprises providing pyromellitic dianhydride and a diamine into the reaction chamber alternately and sequentially. The method further comprises providing the substrate in a second reaction chamber, and providing reactive species generated from NF₃-containing plasma into the reaction chamber to selectively etch the etchable material. In some embodiments, the first reaction chamber and the second reaction chamber are in the same deposition assembly.

### Reaction Chamber and Deposition Assembly

In some embodiments, the current selective etching method is used as a part of a process for manufacturing a semiconductor device. Accordingly, a semiconductor device formed by a method comprising a selective etching process according to the current disclosure is disclosed. The manufacturing process may involve forming a feature, such as a patterned feature. In a yet further aspect, a method of forming a patterned feature on a substrate is disclosed. The method comprises selectively etching material from a first surface of a substrate relative to a second surface of the substrate according to the current disclosure. Also, a method of forming a structure comprising a selective etching process according to the current disclosure is disclosed. The manufacturing process may comprise one or more vapor deposition processes. It may be advantageous to combine the one or more vapor deposition processes with the current selective etching method in one semiconductor processing assembly, such as a cluster tool containing multiple reaction chambers. One or more of said reaction chambers may further be a multi-station reaction chamber, containing, for example, two, four or six deposition stations.

A reaction chamber according to the current disclosure may be part of a cluster tool in which different processes are performed to form an integrated circuit. In some embodiments, a flow-type reactor is utilized. In some embodiments, a cross-flow reactor is used. In some embodiments, a showerhead-type reactor is utilized. In some embodiments, the reaction chamber may be a space-divided reactor. In some embodiments, the reaction chamber may be a batch reactor for processing multiple substrates simultaneously.

In a yet further aspect, a semiconductor processing assembly for processing a substrate is disclosed. The processing assembly comprises a reaction chamber constructed and arranged to hold a substrate having a first surface comprising an etchable material and a second surface covered by an organic polymer layer, a first reactant source containing NF₃ and a second reactant source containing a noble gas. The processing assembly further comprises a plasma generator in fluid communication with the first reactant source and the second reactant source for generating NF₃-containing plasma and a reactant injection system constructed and arranged to provide the NF₃-containing plasma into the reaction chamber.

In some embodiments, the semiconductor processing assembly according to the current disclosure further comprises a second reaction chamber for selectively depositing an organic polymer layer on the second surface. In some embodiments, the semiconductor processing assembly according to the current disclosure comprises a computer programmed to deposit the organic polymer on the second surface before providing the NF₃-containing plasma into the reaction chamber.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative etch rates of different materials indicated in the drawings may deviate from the experimental results, the specifics of which may vary according to process conditions. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

FIG. 1 illustrates an exemplary embodiment of a selective etching method 100 according to the current disclosure as a block diagram. Method 100 may be used to selectively etch a first material relative to a second material from a substrate. The etching method 100 can be used during a formation of a semiconductor structure or device.

At block 102, a substrate is provided in a reaction chamber of a semiconductor processing apparatus. The reaction chamber can form part of cluster tool. In some embodiments, the semiconductor processing apparatus is a single-wafer processing apparatus. Alternatively, the apparatus may be a batch processing apparatus. In some embodiments, the method 100 is performed in a single reaction chamber of a cluster tool, but other, preceding or subsequent, manufacturing phases of the structure or device are performed in additional reaction chambers of the same cluster tool. In some embodiments, the reaction chamber is a processing station of a multi-station chamber. The reaction chamber can be provided with a heater to activate the reactions by elevating the temperature of one or more of the substrate and/or the reactants and/or other gases.

During block 102, the substrate can be brought to a desired temperature and pressure for providing NF₃-containing plasma into the reaction chamber (block 104). A temperature (e.g. of a substrate or a substrate support) within a reaction chamber can be, for example, from about 20° C. to about 200° C., from about 20° C. to about 150° C., from about 20° C. to about 120° C., from about 20° C. to about 100° C., from about 20° C. to about 80° C. or from about 20° C. to about 50° C. As a further example, a temperature within a reaction chamber can be from about 30° C. to about 200° C., or from about 40° C. to about 200° C., from about 50° C. to about 200° C., from about 80° C. to about 200° C., from about 100° C. to about 200° C. or from about 150° C. to about 200° C. Exemplary temperatures within the reaction chamber may be 25° C., 30° C., 45° C., 50° C., 70° C., 100° C., 120° C. or 160° C.

A pressure within the reaction chamber can be less than 760 Torr, for example less than 100 Torr, less than 50 Torr, less than 10 Torr, less than 5 Torr, less than 2 Torr, less than 1 Torr, less than 0.1 Torr or less than 0.05 Torr. In some embodiments, a pressure within the reaction chamber is from about 0.01 Torr to about 30 Torr, or from about 0.01 Torr to about 10 Torr, or from about 0.01 Torr to about 1 Torr. Exemplary reaction chamber pressures include about 25 Torr, about 15 Torr, about 10 Torr, about 5 Torr, 1.5 Torr or about 0.5 Torr. In some embodiments, the pressure is the same throughout the method.

NF₃-containing plasma is provided into the reaction chamber containing the substrate at block 104 to etch the etchable material. Without limiting the current disclosure to any specific theory, the NF₃-containing plasma may have a different effect on different surfaces, and the etch rate brought about by exposing the substrate to NF₃-containing plasma at block 104 may differ on different surfaces.

The duration of providing NF₃-containing plasma into the reaction chamber (NF₃-containing plasma exposure time) may be, for example, from about 0.5 seconds to about 2 minutes. The duration of providing NF₃-containing plasma into the reaction chamber is selected based on the process, tool, depth of the desired etching and other factors. In some embodiments, duration of providing NF₃-containing plasma into the reaction chamber is from about 0.5 seconds to about 1 minute, or from about 0.5 seconds to about 50 seconds, or from about 0.5 seconds to about 40 seconds or from about 0.5 seconds to about 30 seconds, or from about 0.5 seconds to about 10 seconds or from about 0.5 seconds to about 5 seconds. In some embodiments, duration of providing NF₃-containing plasma into the reaction chamber is shorter than about 2 minutes, or shorter than about 1 minute. In some embodiments, the duration of providing NF₃-containing plasma into the reaction chamber (NF₃-containing plasma exposure time) may be longer than about 0.5 seconds or longer than about 1 second or longer than about 10 seconds, or longer than about 20 seconds.

In a set of exemplary etching tests, the etch resistance of a polyimide-containing organic polymer layer was tested. NF₃ and argon were provided into a remote plasma unit, the gas flow speeds for NF₃ ranging from 50 to 250 sccm and for argon from 100 to 500 sccm. The etching tests were performed at temperatures of about 75° C. and about 100° C. The pressure in the reaction chamber was about 1.6 Torr. No etching of the polyimide-containing layers was observed even after a 50-second exposure. At higher NF₃ flow rates, the surface of the polyimide layer was fluorinated, but no thickness decrease was observed. For reference, under similar conditions, the etch rate of silicon oxide is about 3 Å/s, meaning that during a 50-second exposure about 150 nm of silcon oxide is removed. The etch rate of SiN is much lower, about 0.3 Å/s, which would still result in a clearly observable etching of about 15 nm of material. Ammonia was co-flown into the reaction chamber without passing through the plasma generator. This may reduce the etch rate of SiN, and therefore, if the conditions were optimized for SiN etching, higher etch rates could be reached.

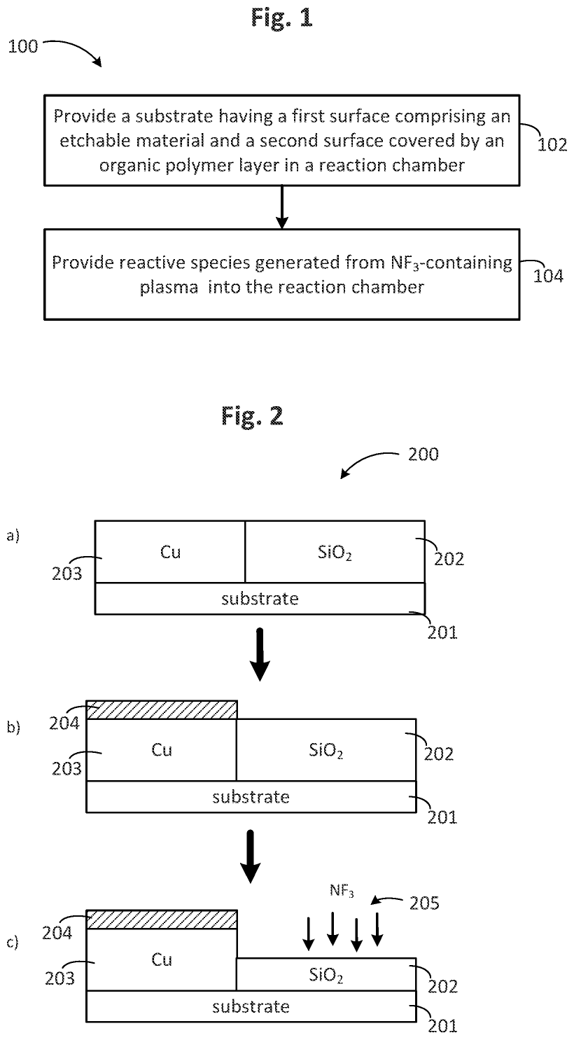

FIG. 2 depicts a method 200 of etching an etchable material on a first surface of a substrate. At panel a) a substrate 201 comprising a first silicon dioxide surface 202 and a second Cu surface 203 is provided in a reaction chamber of a semiconductor processing apparatus. Although Cu is depicted as an example of a metal material in the figure, several other materials, such as metals or metallic materials, could be used in place of, or in combination with, Cu. The first surface is a silicon oxide surface, but similarly to the first surface, various alternatives, as disclosed herein, are possible. The reaction chamber and the corresponding semiconductor processing apparatus may be as described above. The surfaces may be substantially on the same vertical level, or they can be at different heights relative to the substrate surface. The two surfaces may further be two surfaces in a 3D structure. For example, the first surface may form a bottom of a gap, whereas the second surface may form a sidewall of the gap.

At panel b) an organic polymer layer 204, such as a polyimide-comprising layer is deposited on the second surface 203.

At panel c) NF₃-containing plasma 205 (indicated by the downward arrows) is generated and provided into the reaction chamber to etch the material of the first surface 202. The organic polymer layer 204 and the second surface 203 under it stay substantially intact. Particularly, a plasma etch may etch the material anisotropically, whereby the sideways etching of the material of the second surface 203 may be avoided. After the etching process, the organic polymer layer 204 may be removed, or the process may be continued. Advantageously, the organic polymer layer 204 may be utilized in area-selective deposition processes to direct deposition on the (etched) first surface 202.

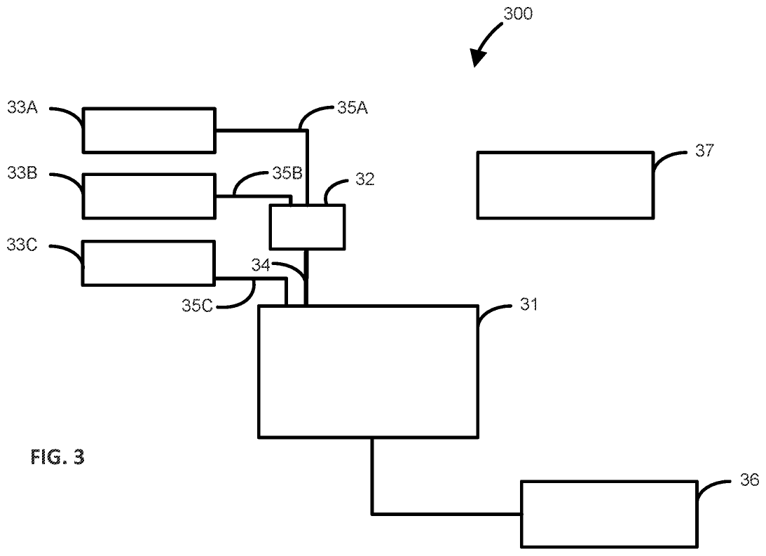

FIG. 3 illustrates an exemplary embodiment of a semiconductor processing assembly 300 according to the current disclosure in a schematic form. As a schematic representation of a semiconductor processing assembly, many components have been omitted for simplicity of illustration, and such components may include, for example, various valves, manifolds, purifiers, heaters, containers, vents, and/or bypasses.

The semiconductor processing assembly 300 may comprise a reaction chamber 31, a plasma generator 32 for generating plasma, a NF₃ source 33A for providing gaseous NF₃ for generating NF₃-containing plasma by the plasma generator 32, a gas source 33B for providing a noble gas in a gas phase to generate active species by the plasma generator 32, a pathway 34 disposed between the plasma generator 32 and the reaction chamber 31, and gas lines 35A and 35B providing a fluid communication path from the sources 33A and 33B with the reaction chamber 31. The semiconductor processing assembly further comprises an additional gas source 33C, connected by a line 35C to the reaction chamber 31. The additional gas provided into the reaction chamber from the additional gas source 33C does not pass through the plasma generator 32. In the embodiment of FIG. 3, the plasma generator 32 is a remote plasma unit and the semiconductor processing assembly 300 comprises three gas sources 33A, 33B and 33C. Two of the gas sources 33A, 33B are connected to the reaction chamber 31 through the plasma generator 32, so they may be considered plasma reactant sources. Depending on the process specifics, the in addition to the additional gas source 33C, the semiconductor processing assembly 300 may comprise one or more bypasses so that the sources 33A and/or 33B may provide a gas into the reaction chamber 31 without passing through a plasma generator 32. The pathway 34 and gas lines 35A, 35B and 35C, together with the necessary valves, manifolds, etc., constitute a reactant injection system to provide NF₃-containing plasma from the plasma generator into the reaction chamber 32 in vapor phase. The semiconductor processing assembly 300 may further comprise further gas sources, and corresponding gas lines, valves, etc. to provide purge gases or other process gases into the reaction chamber 31.

FIG. 3 additionally illustrates an exhaust gas source 36. An exhaust source 36 may comprise one or more vacuum pumps. The embodiment of a semiconductor processing assembly additionally comprises and a controller 37. The controller 37 includes electronic circuitry and software to selectively operate valves, manifolds, heaters, pumps and other components included in the semiconductor processing assembly 300. Such circuitry and components operate to provide gases, regulate temperature, pressure etc. to provide proper operation of the semiconductor processing assembly 300. Controller 37 can include modules such as a software or hardware component, which performs certain tasks. A module may be configured to reside on the addressable storage medium of the control system and be configured to execute one or more processes.

The semiconductor processing assembly of FIG. 3 may be a part of a cluster tool comprising multiple reaction chambers. The reaction chamber 31 may be an individual processing station of a multi-station tool. In some embodiments, the semiconductor processing assembly comprises a hot-wall, cold-wall or warm-wall type of reaction chamber.

During operation of semiconductor processing assembly 300, substrates, such as semiconductor wafers (not illustrated), are transferred from, e.g., a substrate handling system to reaction chamber 31. Once substrate(s) are transferred to reaction chamber 31, one or more gases from gas sources 33A or 33C, such as for generating reactive species and/or purge gases, are introduced into reaction chamber 31.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various methods and assemblies, and other features, functions, acts, and/or properties disclosed herein, as well as any and all equivalents thereof.

1. A method of selectively etching material from a first surface of a substrate relative to a second surface of the substrate, the method comprising:
providing a substrate having a first surface comprising an etchable material and a second surface covered by an organic polymer layer in a reaction chamber; and
providing reactive species generated from NF₃-containing plasma into the reaction chamber to selectively etch the etchable material.

2. The method of claim 1, wherein the organic polymer layer comprises polyimide.

3. The method of claim 1, wherein the organic polymer layer is substantially not etched.

4. The method of claim 1, wherein the NF₃-containing plasma further comprises at least one noble gas.

5. The method of claim 4, wherein the NF₃-containing plasma comprises argon.

6. The method of claim 1, wherein the NF₃-containing plasma is generated from a gas mixture consisting substantially only of argon and NF₃.

7. The method of claim 1, wherein the NF₃-containing plasma is generated from a gas mixture containing between about 1% and about 90% NF₃.

8. The method of claim 1, wherein the NF₃-containing plasma is generated remotely.

9. The method of claim 1, wherein the first surface and the second surface have a chemically different composition.

10. The method of claim 10, wherein the first surface comprises silicon.

11. The method of claim 11, wherein the first surface comprises one or more of SiO₂, SiN, SiC, SiCN, SiON, SiOC, and SiOCN.

12. The method of claim 9, wherein the second surface comprises a metal.

13. The method of claim 12, wherein the metal is selected from the group consisting of aluminum, copper, tungsten, cobalt, nickel, niobium, iron, molybdenum, zinc, ruthenium, manganese, titanium, tin, and vanadium.

14. The method of claim 12, wherein the second surface comprises one or more of an elemental metal, metal oxide, or a metal nitride.

15. The method of claim 9, wherein the first surface and the second surface form different surfaces of a structure.

16. The method of claim 15, wherein the second surface forms an inside surface of a gap.

17. A method of selectively etching material from a first surface of a substrate relative to a second surface of the substrate, the method comprising:
providing a substrate having a first surface comprising an etchable material, and a second surface in a first reaction chamber;
selectively depositing a layer comprising polyimide on the second surface by a cyclic deposition process, wherein the cyclic deposition process comprises providing pyromellitic dianhydride and a diamine into the first reaction chamber alternately and sequentially;
providing the substrate in a second reaction chamber; and
providing reactive species generated from NF₃-containing plasma into the reaction chamber to selectively etch the etchable material.

18. The method of claim 17, wherein the first reaction chamber and the second reaction chamber are in the same deposition assembly.

19. A semiconductor processing assembly for processing a substrate, the processing assembly comprising:
a reaction chamber constructed and arranged to hold a substrate having a first surface comprising an etchable material and a second surface covered by an organic polymer layer;
a first reactant source comprising NF₃;
a second reactant source comprising a noble gas;
a plasma generator in fluid communication with the first reactant source and the second reactant source for generating NF₃-containing plasma; and
a reactant injection system constructed and arranged to provide the NF₃-containing plasma into the reaction chamber.

20. The semiconductor processing assembly of claim 19, further comprising a second reaction chamber for selectively depositing an organic polymer layer on the second surface.
